(19) United States
(12) Patent Application Publication
(10) Pub. No.: US 2023/0327777 A1
(43) Pub. Date: Oct. 12, 2023

(54) Optical Receiver Element with Integrated Front End

(71) Applicant: Fathom Radiant, PBC, Boulder, CO (US)

(72) Inventors: Ryan Boesch, Louisville, CO (US); J. Israel Ramirez, Denver, CO (US); Keith Behrman, Boulder, CO (US)

(21) Appl. No.: 18/194,755

(22) Filed: Apr. 3, 2023

Related U.S. Application Data
(60) Provisional application No. 63/328,135, filed on Apr. 6, 2022.

(51) Int. Cl. H04B 10/60

(52) U.S. Cl. CPC H04B 10/60

(57) ABSTRACT

Mass-transfer printing an optical receiver element that also has part of the receiver front end integrated with the purpose of lowering the capacitance exposed to the sensitive input of the RX frontend. An optical receiver element with integrated front end where the silicon layer of the optical element is used to implement a silicon field-effect transistor process which is then used to incorporate the resistive transimpedance amplifier adjacent to the photodiode, resulting in a lower capacitance.

This application claims the benefit of pat. app. No. 63/328,135, entitled “Optical Receiver Element with Integrated Front End,” and filed 6 Apr. 2022 and incorporates it by reference.

### BACKGROUND OF THE INVENTION

### Field of the Invention

The present invention relates to optical receiver elements with integrated front ends for low-energy-per-bit data transmission.

### Discussion of Related Art

FIGS. 1A (prior art) and 1B (prior art) show a device 100 comprising a photodiode (PD) 122 which is mass-transfer printed (MTP) at 102 on a standard silicon logic process 130 to serve as an optical receiver element. FIG. 1A is a schematic diagram of the device. FIG. 1B is a cross sectional view of the physical device.

The PD 122 is a two-terminal device having silicon layer 132 with the terminals 134, 136 commonly referred to as cathode and anode. In a common-cathode architecture, the cathode 134 can be shared 108 among multiple PD or connected to the silicon logic metal stack 130 via pad 104 on a per device basis. The anode terminal 136 provides the unique path for current to flow which is modulated in some fashion to encode data. In prior art, this anode was routed with a redistribution layer (RDL) 137 to a pad 106 connected to the silicon logic metal stack 130 and a receiver (RX) frontend 120. The RX frontend 120 is exposed to a small capacitance 114 at the output due to on-chip interconnect routing to the downstream receiver blocks 118. The combination of the RDL 137, pad 106, and silicon logic metal stack 131 results in a large capacitance 112 to ground 110 which either (1) lowers the speed of the RX frontend 120 or (2) requires increased power to overcome.

### SUMMARY OF THE INVENTION

In an embodiment, the silicon layer of the PD is used to implement a silicon field-effect transistor (FET) process which is then used to incorporate some portion of the RX frontend adjacent to the PD, resulting in a lower capacitance at the input to the RX frontend. This in turn allows either higher speed operation at the same power or lower power for the same speed. A combined PD and partial RX frontend chiplet or die frees up area in the die below and enables the partial RX frontend design to be independent of the process node below.

Embodiments implement mass-transfer printing of an optical receiver element that also has part of the receiver front end integrated, with the purpose of lowering the capacitance exposed to the sensitive input of the RX frontend.

An optical device is formed of an optical receiver, a die having a logic layer which is electrically connected to the optical receiver, and an electronic receiver frontend. A portion of the electronic receiver frontend is integrated with the optical receiver and a separate portion of the electronic receiver frontend is implemented in the logic layer. optionally, the entire electronic receiver frontend is integrated with the optical receiver.

For example, the optical receiver is transfer printed onto the die and metal is patterned as a redistribution layer. The optical receiver may be a Ge-on-Si photodetector or a silicon photodetector. The receiver may be a waveguide-coupled detector.

The integrated portion of the receiver frontend may be a resistive transimpedance amplifier (RTIA) and can include a gain stage and offset current trim after the RTIA. The integrated portion of the receiver frontend may include, alone or in any combination, an RTIA, a comparator slicer, a low-pass filter to remove high-frequency noise from the received signal, a high-pass filter to remove low-frequency noise from the received signal, a clock recovery circuit to extract a clock signal from the received data, a digital signal processing circuit to process the received signal, a continuous time linear equalizer to compensate for signal distortion caused by the transmission medium, or a decision feedback equalizer configured to reduce inter-symbol interference in the received signal.

### BRIEF DESCRIPTION OF THE DRAWINGS

FIG. 1A (Prior Art) is a schematic block diagram of an optical receiver comprising a photodiode mass-transfer printed onto a silicon logic process implementing a receiver frontend.

FIG. 1B (Prior Art) is a cross section of the physical stackup of the schematic block diagram in FIG. 1A.

FIG. 2A is a schematic block diagram of an improved optical receiver comprising a photodiode with integrated RX frontend mass-transfer printed onto a silicon logic process implementing the remainder of the receiver frontend.

FIG. 2B is a cross section of the physical stackup of the schematic block diagram in FIG. 2A.

FIG. 3 is a schematic block diagram of an improved optical receiver comprising a photodiode with integrated resistive transimpedance amplifier (RTIA) mass-transfer printed onto a silicon logic process implementing the remainder of the receiver frontend.

### DETAILED DESCRIPTION OF THE INVENTION

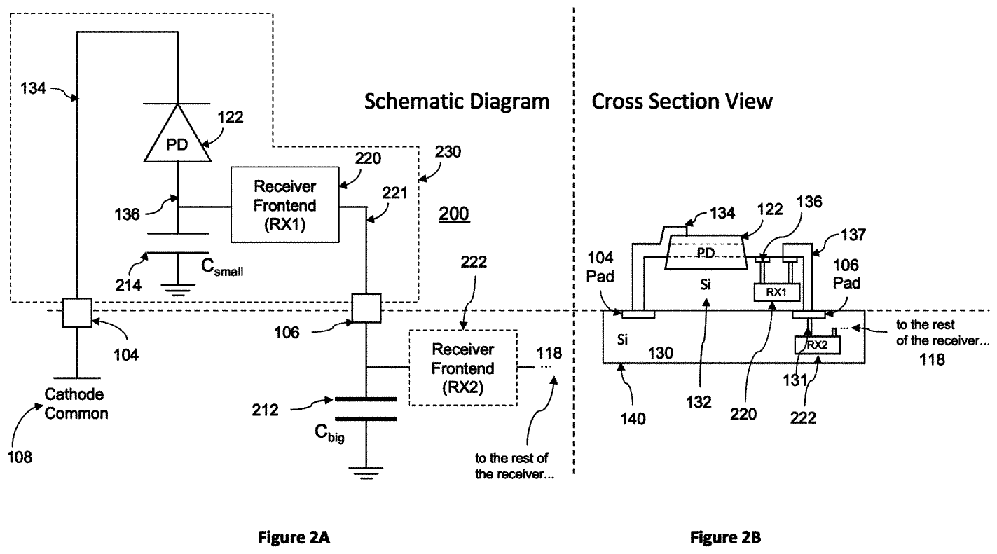

FIGS. 2A and 2B show a device 200 wherein the silicon layer 132 of the PD 122 is used to implement a silicon field-effect transistor (FET) process which is then used to integrate a portion (RX1) 220 of the RX frontend adjacent to the PD 122, resulting in a lower input capacitance 214, while the rest of the RX frontend (RX2) 222 is disposed within silicon logic layer 130. The RX frontend portion (RX1) 220, which would otherwise be implemented with circuit blocks composed of FETs and passives in the silicon logic layer 130, is integrated into the PD silicon layer 132 of the PD 122 with similar circuitry composed of FETs and passives in that layer 132 resulting in lower capacitance 214. This in turn allows either (1) higher speed operation at the same power or (2) lower power for the same speed. Though the capacitance 212 from the RDL 137 (for MTP embodiment), pad 106, and silicon logic metal stack 131 remains similar to the prior art; it's transferred from the sensitive input node 106 of RX1 220 to the driven output 221. The combined PD and RX frontend chiplet 230 additionally frees up area in the die below silicon logic layer 130 (not shown) for other purposes and enables the RX frontend design 220 to be independent of the process node below. In some embodiments, the entire RX frontend will be integrated into RX1 220 in the RX frontend chiplet 230, in which case the RX frontend 222 implemented in the standard silicon logic process will comprise pass through metal routing to the rest of the receiver 118.

Alternative stacking methods can also be used. In one alternative stacking method, indium bumps would be formed on the optical device and the electrical connection would be established with pressure directly onto the pad.

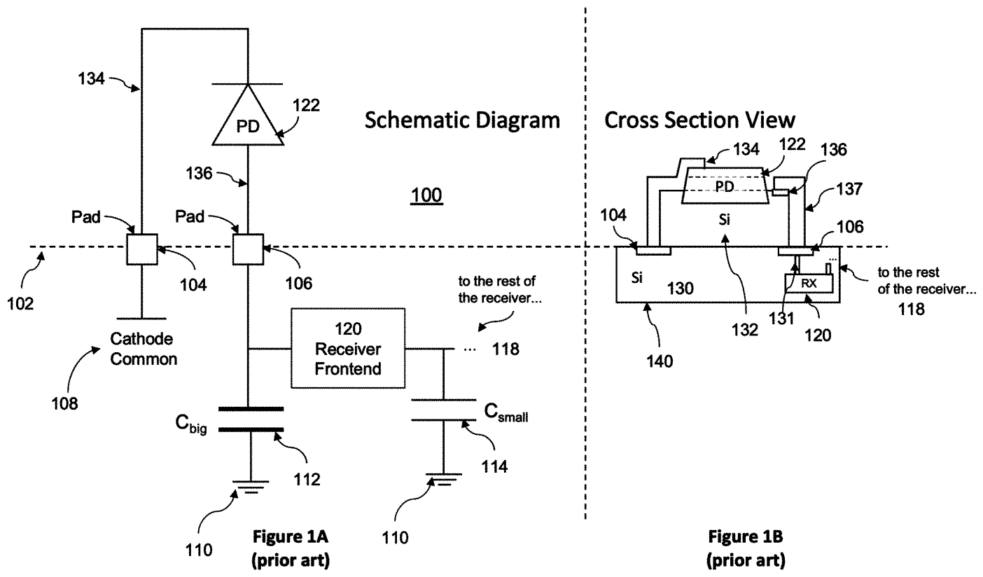

As in the case of the device of FIG. 1, this example is a common-cathode architecture, wherein cathode 134 is shared 108 among multiple PD or connected to the silicon logic metal stack 130 via pad 104 on a per device basis. The anode terminal 136 provides the unique path for current to flow which is modulated in some fashion to encode data. Downstream receiver blocks 118 implement the receiver backend. As an alternative a common-anode architecture could be used. In this case 108 would be the common anode, connected through pad 104 to the anode 136 of a PD 122 with reversed polarity and the cathode 134 is connected to the RX front end (RX1) 220 and sees reduced input capacitance 214.

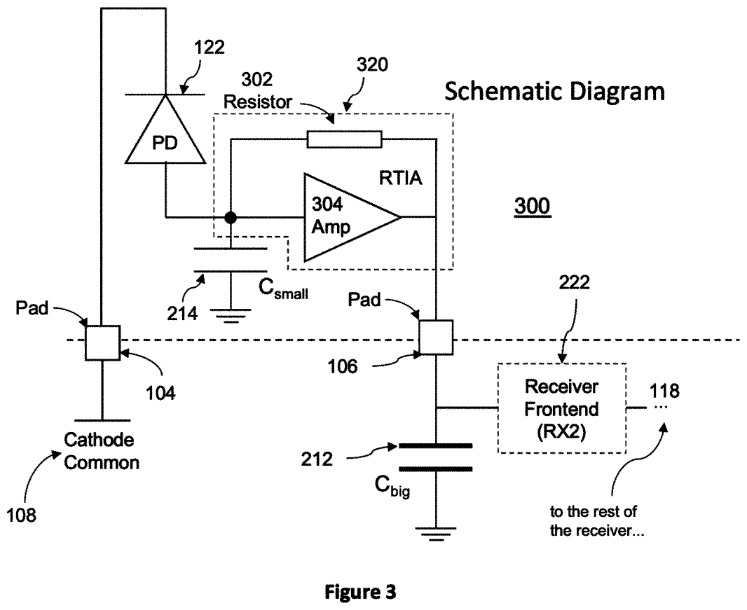

FIG. 3 shows a device wherein the PD silicon layer 132 of the PD 122 of FIG. 2A is used to implement a silicon field-effect transistor (FET) process which is then used to incorporate the RTIA 320 of the RX frontend adjacent to the PD, resulting in a lower capacitance. The RTIA 320 in this example consists of a transimpedance amplifier 304 with feedback resistor 302. The remainder of the RX frontend 222 is implemented in the silicon logic layer 130.

In the embodiment shown, the optical receiver is transfer printed, and then metal is patterned as an RDL to complete the connections between the pads.

Advantages of this embodiment include lower power consumption and higher speed operation, enabling the receiver element's process node to be independent of the logic node, and improvement of the logic node's area utilization.

In other embodiments, circuitry in addition to or as an alternative to the RTIA 320 can be included in the RX frontend 220 of the RX frontend chiplet 230. Examples include an offset current trim, gain stage, comparator slicer, clock and data recovery circuitry, a low-pass filter to remove high-frequency noise, or a high-pass filter to remove low-frequency noise. Equalization circuitry can be included in the RX frontend 220 such as a continuous time linear equalizer, decision feedback equalizer, or digital signal processing. In another embodiment, the entire RX frontend is contained in the RX frontend chiplet 230.

While the exemplary preferred embodiments of the present invention are described herein with particularity, those skilled in the art will appreciate various changes, additions, and applications other than those specifically mentioned, which are within the spirit of this invention.

What is claimed is:

1. An optical device comprising:
an optical receiver;
a die having a logic layer and electrically connected to the optical receiver; and
an electronic receiver frontend;
wherein a portion of the electronic receiver frontend is integrated with the optical receiver to form an integrated portion of the electronic receiver frontend, and
wherein a separate portion of the electronic receiver frontend is implemented in the logic layer.

2. The optical device of claim 1 wherein the optical receiver is transfer printed onto the die and metal is patterned as a redistribution layer.

3. The optical device of claim 1, wherein the optical receiver is a Ge-on-Si photo-detector.

4. The optical device of claim 1, wherein the integrated portion of the receiver frontend is a resistive transimpedance amplifier (RTIA).

5. The optical device of claim 4 wherein the wherein the optical receiver is transfer printed onto the die and metal is patterned as a redistribution layer.

6. The optical device of claim 4, wherein the integrated portion of the receiver frontend further comprises a gain stage and offset current trim after the RTIA.

7. The optical device of claim 1, wherein the integrated portion of the receiver frontend includes a comparator slicer.

8. The optical device of claim 1, wherein the optical receiver is a silicon photodetector.

9. The optical device of claim 1, wherein the optical receiver is a waveguide-coupled detector.

10. The optical device of claim 1, wherein the integrated portion of the receiver frontend includes a low-pass filter to remove high-frequency noise from a received signal.

11. The optical device of claim 1, wherein the integrated portion of the receiver frontend includes a high-pass filter to remove low-frequency noise from a received signal.

12. The optical device of claim 1, wherein the integrated portion of the receiver frontend includes a clock recovery circuit to extract a clock signal from received data.

13. The optical device of claim 1, wherein the integrated portion of the receiver frontend includes a digital signal processing circuit to process a received signal.

14. The optical device of claim 1, wherein the integrated portion of the receiver frontend includes a continuous time linear equalizer to compensate for signal distortion caused by the transmission medium.

15. The optical device of claim 1, wherein the integrated portion of the receiver frontend includes a decision feedback equalizer configured to reduce inter-symbol interference in a received signal.

16. An optical device comprising:
an optical receiver;
a die having a logic layer and electrically connected to the optical receiver; and
an electronic receiver frontend;
wherein the electronic receiver frontend is integrated with the optical receiver.

17. The optical device of claim 16 wherein the optical receiver is transfer printed onto the die and metal is patterned as a redistribution layer.

18. The optical device of claim 16, wherein the optical receiver is a Ge-on-Si photodetector.

19. The optical device of claim 16, wherein the optical receiver is a silicon photodetector.

20. The optical device of claim 16, wherein the optical receiver is a waveguide-coupled detector.
